(19) United States
(12) Patent Application Publication
(10) Pub. No.: US 2024/0237557 A1
(43) Pub. Date: Jul. 11, 2024

(54) SUPERCONDUCTING DEVICE, METHOD OF MANUFACTURING SUPERCONDUCTING DEVICE, AND LAMINATED BODY

(71) Applicant: Fujitsu Limited, Kawasaki-shi, (JP)

(72) Inventor: Makoto NAKAMURA, Kawasaki (JP)

(73) Assignee: Fujitsu Limited, Kawasaki-shi, (JP)

(21) Appl. No.: 18/351,575

(22) Filed: Jul. 13, 2023

Related U.S. Application Data
(63) Continuation of application No. PCT/JP2021/011752, filed on Mar. 22, 2021.

(51) Int. Cl. H10N 60/82; H10N 60/01; H10N 60/12; H10N 69/00

(52) U.S. Cl. CPC H10N 60/82; H10N 60/0912; H10N 60/12; H10N 69/00

(57) ABSTRACT

A superconducting device includes: a substrate; a through hole provided in the substrate; a through electrode provided in the through hole, the through hole including a first portion and a second portion provided between the first portion and an inner wall surface of the through hole, in which the second portion is formed of a material including a first metal exhibiting superconductivity at a temperature lower than a criteria; a junction electrode electrically coupled to the through electrode, the junction electrode having at least a part provided outside the through hole and being formed of a material including a second metal exhibiting superconductivity at a temperature lower than a criteria; and a partition wall provided between the through electrode and the junction electrode and being formed of a material including the first metal, wherein a melting point of the first metal is higher than that of the second metal.

### CROSS-REFERENCE TO RELATED APPLICATION

This application is a continuation application of International Application PCT/JP2021/011752 filed on Mar. 22, 2021 and designated the U.S., the entire contents of which are incorporated herein by reference.

### FIELD

The disclosed technology relates to a superconducting device, a method of manufacturing a superconducting device, and a laminated body.

### BACKGROUND

The following technology is known as a technology related to a superconducting device having a structural portion exhibiting superconductivity.

For example, a semiconductor device is known that includes a base substrate, a carrier substrate, and a buried metallization layer that intermediates the base substrate and the carrier substrate. A method of manufacturing the semiconductor device includes the following processing. A top metallization layer of a first conductive metal material is formed on a top surface of the carrier substrate. Next, unfilled through-substrate-vias are formed in the carrier substrate to the buried metallization layer. Next, an under bump metallization layer of a second conductive metal material is formed on surfaces defining the unfilled through-substrate-vias and a perimeter surrounding the unfilled through-substrate-vias on the carrier substrate, and on the first conductive metal material layer. The under bump metallization layer is coupled to the buried metallization layer and the top metallization layer. The first conductive metal material and the second conductive metal material are different. Next, a sacrificial layer is deposited and patterned to form openings exposing the unfilled through-substrate-vias and the perimeter surrounding the unfilled through-substrate-vias on the carrier substrate and on the top metallization layer. Next, the openings are filled with a third conductive metal material to form a filled through-substrate-via. Next, the sacrificial layer is removed to form a cylindrical shaped solder bump self-aligned to the filled through-substrate-via.

Examples of the related art include: [Patent Document 1] Japanese National Publication of International Patent Application No. 2020-520090.

### SUMMARY

According to an aspect of the embodiments, there is provided a superconducting device including: a substrate; a through hole provided in the substrate; a through electrode that is an electrode provided in the through hole and that includes a first portion and a second portion provided between the first portion and an inner wall surface of the through hole, in which the second portion is formed of a material that includes a first metal that exhibits superconductivity at a temperature equal to or lower than a predetermined temperature; a junction electrode that is an electrode electrically coupled to the through electrode, that has at least a part provided outside the through hole, and that is formed of a material that includes a second metal that exhibits superconductivity at a temperature equal to or lower than a predetermined temperature; and a partition wall that is provided between the through electrode and the junction electrode and that is formed of a material that includes the first metal, wherein a melting point of the first metal is higher than a melting point of the second metal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating an example of a configuration of a superconducting device according to an embodiment of the disclosed technology;

FIG. 2 is a view illustrating an example of a configuration of a superconducting qubit element according to the embodiment of the disclosed technology;

FIG. 3A is a cross-sectional view illustrating an example of a method of manufacturing the superconducting device according to the embodiment of the disclosed technology;

FIG. 3B is a cross-sectional view illustrating an example of the method of manufacturing the superconducting device according to the embodiment of the disclosed technology;

FIG. 3C is a cross-sectional view illustrating an example of the method of manufacturing the superconducting device according to the embodiment of the disclosed technology;

FIG. 3D is a cross-sectional view illustrating an example of the method of manufacturing the superconducting device according to the embodiment of the disclosed technology;

FIG. 3E is a cross-sectional view illustrating an example of the method of manufacturing the superconducting device according to the embodiment of the disclosed technology;

FIG. 3F is a cross-sectional view illustrating an example of the method of manufacturing the superconducting device according to the embodiment of the disclosed technology;

FIG. 3G is a cross-sectional view illustrating an example of the method of manufacturing the superconducting device according to the embodiment of the disclosed technology;

FIG. 3H is a cross-sectional view illustrating an example of the method of manufacturing the superconducting device according to the embodiment of the disclosed technology;

FIG. 3I is a cross-sectional view illustrating an example of the method of manufacturing the superconducting device according to the embodiment of the disclosed technology;

FIG. 3J is a cross-sectional view illustrating an example of the method of manufacturing the superconducting device according to the embodiment of the disclosed technology;

FIG. 3K is a cross-sectional view illustrating an example of the method of manufacturing the superconducting device according to the embodiment of the disclosed technology;

FIG. 3L is a cross-sectional view illustrating an example of the method of manufacturing the superconducting device according to the embodiment of the disclosed technology;

FIG. 3M is a cross-sectional view illustrating an example of the method of manufacturing the superconducting device according to the embodiment of the disclosed technology;

FIG. 4A is a cross-sectional view illustrating an example of a method of manufacturing the superconducting device according to the embodiment of the disclosed technology;

FIG. 4B is a cross-sectional view illustrating an example of the method of manufacturing the superconducting device according to the embodiment of the disclosed technology;

FIG. 4C is a cross-sectional view illustrating an example of the method of manufacturing the superconducting device according to the embodiment of the disclosed technology;

FIG. 4D is a cross-sectional view illustrating an example of the method of manufacturing the superconducting device according to the embodiment of the disclosed technology;

FIG. 4E is a cross-sectional view illustrating an example of the method of manufacturing the superconducting device according to the embodiment of the disclosed technology;

FIG. 4F is a cross-sectional view illustrating an example of the method of manufacturing the superconducting device according to the embodiment of the disclosed technology;

FIG. 4G is a cross-sectional view illustrating an example of the method of manufacturing the superconducting device according to the embodiment of the disclosed technology;

FIG. 4H is a cross-sectional view illustrating an example of the method of manufacturing the superconducting device according to the embodiment of the disclosed technology;

FIG. 4I is a cross-sectional view illustrating an example of the method of manufacturing the superconducting device according to the embodiment of the disclosed technology;

FIG. 4J is a cross-sectional view illustrating an example of the method of manufacturing the superconducting device according to the embodiment of the disclosed technology;

FIG. 4K is a cross-sectional view illustrating an example of the method of manufacturing the superconducting device according to the embodiment of the disclosed technology;

FIG. 5 is a cross-sectional view illustrating an example of a configuration of the superconducting device according to the embodiment of the disclosed technology;

FIG. 6 is a cross-sectional view illustrating an example of a configuration of a superconducting device according to an embodiment of the disclosed technology;

FIG. 7 is a cross-sectional view illustrating an example of a configuration of the superconducting device according to the embodiment of the disclosed technology;

FIG. 8 is a cross-sectional view illustrating an example of a configuration of a laminated body according to an embodiment of the disclosed technology;

FIG. 9 is a cross-sectional view illustrating an example of a configuration of the laminated body according to the embodiment of the disclosed technology;

FIG. 10 is a cross-sectional view illustrating an example of a configuration of the laminated body according to the embodiment of the disclosed technology; and

FIG. 11 is a cross-sectional view illustrating an example of a configuration of the laminated body according to the embodiment of the disclosed technology.

### DESCRIPTION OF EMBODIMENTS

An object of the disclosed technology is to suppress stress associated with temperature change in a superconducting device.

A quantum computer is considered to have overwhelming processing capability as compared with a conventional computer by using quantum mechanical phenomena such as superposition and quantum entanglement. As a device for implementing the quantum computer, for example, a superconducting device using a Josephson device including a superconducting material has been proposed. The Josephson device is a switching element using a tunnel effect of a current in a superconducting state. The superconducting device is usually used in a cryogenic environment because superconductivity is exhibited in a cryogenic environment such as several mK.

On the other hand, it is considered that high density mounting becomes possible by laminating superconducting devices on each other or laminating a superconducting device and another device. In the superconducting device, it is considered to use a through electrode as means for implementing three-dimensional mounting. Specifically, a superconducting device including a substrate, a through electrode penetrating the substrate, and a junction electrode electrically coupled to the through electrode is assumed. The superconducting device is laminated on another device via the junction electrode by reflow processing. In the reflow processing, the superconducting device is exposed to a temperature equal to or higher than a melting point of the junction electrode. In a case where the junction electrode includes, for example, Sn, Pb, or an alloy thereof, the melting point of the junction electrode is equal to or higher than 200° C., and a reflow temperature is set to about 300° C. In other words, in the superconducting device, a difference between a temperature at the time of mounting and a temperature at the time of use is equal to or higher than 500° C. Therefore, in the superconducting device used in the cryogenic environment, as compared with a general device used in a normal temperature environment, volume fluctuation associated with expansion and contraction of the through electrode and the junction electrode increases, and there is a high risk that damage such as cracks occurs in these electrodes. In particular, in a structure in which a through electrode and a junction electrode are integrally formed as described in Patent Document 1, deposition of the structure in which the through electrode and the joint electrode are integrated becomes large, so that the volume fluctuation and stress associated with volume fluctuation become more remarkable.

Hereinafter, an example of embodiments of the disclosure will be described with reference to the drawings. Note that, in the respective drawings, the same or equivalent components and portions are given the same reference signs and redundant description will be omitted as appropriate.

### First Embodiment

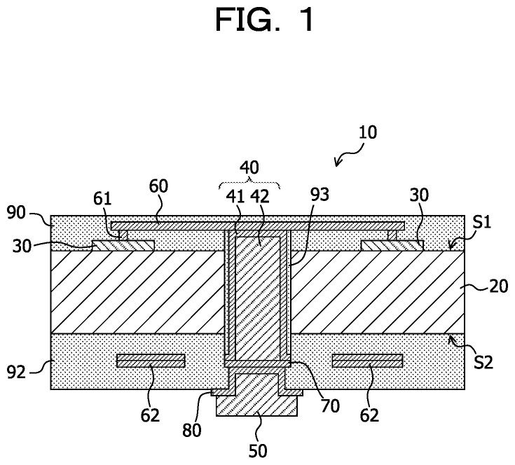

FIG. 1 is a cross-sectional view illustrating an example of a configuration of a superconducting device 10 according to a first embodiment of the disclosed technology. The superconducting device 10 includes a substrate 20, superconducting qubit elements 30, a through electrode 40, and a junction electrode 50.

The substrate 20 includes an insulator or a semiconductor. Use of a semiconductor such as silicon as the substrate 20 facilitates application of an existing semiconductor processing technology.

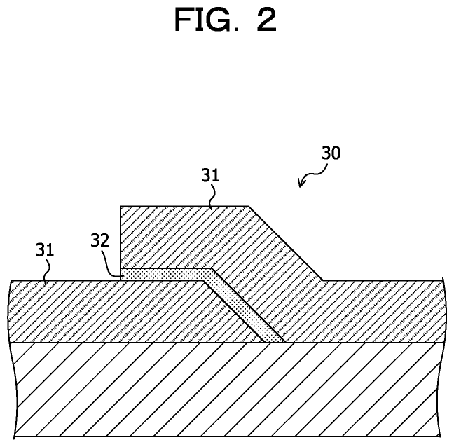

The superconducting qubit elements 30 are provided on a side of a surface S1 of the substrate 20. The superconducting qubit element 30 is an element that forms a coherent two-level system using superconductivity. In the present embodiment, the superconducting qubit element 30 includes a Josephson device illustrated in FIG. 2. The Josephson device includes a pair of superconductors 31 that exhibit superconductivity at a temperature equal to or lower than a predetermined critical temperature, and an ultrathin insulator 32 having a thickness of about several nm sandwiched between the pair of superconductors 31. The superconductor 31 may be, for example, aluminum, and the insulator 32 may be, for example, aluminum oxide. A wiring 60 is coupled to the superconducting qubit elements 30 via vias 61. Each of the vias 61 and the wiring 60 includes a high melting point metal that exhibits superconductivity at a temperature equal to or lower than a predetermined temperature. Details of the high melting point metal will be described later. The surface S1 of the substrate 20 is covered with an insulator layer 90 including an insulator such as SiO₂, and the superconducting qubit elements 30, the vias 61, and the wiring 60 are buried in the insulator layer 90.

The through electrode 40 penetrates the substrate 20. One end of the through electrode 40 is coupled to the wiring 60 provided on the side of the surface S1 of the substrate 20, and the other end is coupled to the junction electrode 50 via a cap film 70 provided on a side of a surface S2 opposite to the surface S1 of the substrate 20. In other words, the through electrode 40 functions as a transmission path for transmitting a qubit output from the superconducting qubit element 30 provided on the side of the surface S1 of the substrate 20 to the junction electrode 50 provided on the side of the surface S2 of the substrate 20.

The through electrode 40 includes an outer portion 41 and an inner portion 42. The outer portion 41 includes a high melting point metal that exhibits superconductivity at a temperature equal to or lower than a predetermined temperature, and surrounds the inner portion 42. The inner portion 42 includes a low melting point metal that exhibits superconductivity at a temperature equal to or lower than a predetermined temperature. In other words, the inside of the through electrode 40 is filled with the low melting point metal that exhibits superconductivity at the temperature equal to or lower than the predetermined temperature. Details of the low melting point metal will be described later. An end portion of the through electrode 40 on the side of the surface S2 of the substrate 20 is closed by the cap film 70. The cap film 70 includes a high melting point metal that exhibits superconductivity at a temperature equal to or lower than a predetermined temperature. The cap film 70 functions as a partition wall separating the through electrode 40 and the junction electrode 50. The low melting point metal constituting the inner portion 42 of the through electrode 40 is completely surrounded (sealed) by the high melting point metal constituting the through electrode 40 and the high melting point metal constituting the cap film 70. An insulating film 93 including an insulator such as SiO₂ is provided between the substrate 20 and the through electrode 40. In other words, the substrate 20 and the through electrode 40 are electrically separated from each other. The surface S2 of the substrate 20 is covered with an insulator layer 92. The cap film 70 is buried in the insulator layer 92, and the end portion of the through electrode 40 on the side of the surface S2 of the substrate 20 reaches the inside of the insulator layer 92.

The junction electrode 50 has a form of a so-called bump, and functions as an external coupling terminal for joining the superconducting device 10 to another device. The junction electrode 50 is provided on the side of the surface S2 of the substrate 20, and is coupled to the through electrode 40 via the cap film 70 and a base film 80. In the present embodiment, the junction electrode 50 is provided immediately below the through electrode 40. The junction electrode 50 includes a low melting point metal that exhibits superconductivity at a temperature equal to or lower than a predetermined temperature. The junction electrode 50 includes a portion buried in the insulator layer 92 and a portion exposed from a surface of the insulator layer 92. The base film 80 is interposed between the junction electrode 50 and the insulator layer 92. The base film 80 functions as a so-called under bump metal, and has a function of suppressing diffusion of the low melting point metal constituting the junction electrode 50 into the insulator layer 92 and a function of enhancing adhesion between the junction electrode 50 and the insulator layer 92. Furthermore, the base film 80 functions as a partition wall separating the through electrode 40 and the junction electrode 50. The base film 80 includes a high melting point metal that exhibits superconductivity at a temperature equal to or lower than a predetermined temperature.

In the insulator layer 92, dummy wirings 62 that are not electrically coupled to the superconducting qubit elements 30 are provided. A potential of the dummy wiring 62 may be, for example, a ground potential or floating. The dummy wiring 62 is provided as needed in order to balance a wiring density on the side of the surface S1 of the substrate 20 and a wiring density on the side of the surface S2 of the substrate 20. In a case where the wiring density on the side of the surface S1 of the substrate 20 and the wiring density on the side of the surface S2 of the substrate 20 are not uniform, warpage occurring in the substrate 20 becomes remarkable. By providing the dummy wiring 62 on the side of the surface S2 of the substrate 20 as appropriate and balancing the wiring densities of both surfaces of the substrate 20, it is possible to suppress the warpage occurring in the substrate 20. Note that a wiring electrically coupled to the superconducting qubit element 30 or a wiring having a specific electrical function may be provided on the side of the surface S2 of the substrate 20. Furthermore, the dummy wiring and the wiring having the specific electrical function may be provided so as to be mixed on the side of the surface S2 of the substrate 20.

As described above, each of the vias 61, the wiring 60, the outer portion 41 of the through electrode 40, the cap film 70, and the base film 80 includes a high melting point metal that exhibits superconductivity at a temperature equal to or lower than a predetermined temperature. The respective high melting point metals constituting the vias 61, the wiring 60, the outer portion 41 of the through electrode 40, the cap film 70, and the base film 80 are preferably the same metals as each other. Furthermore, as described above, each of the inner portion 42 of the through electrode 40 and the junction electrode 50 includes a low melting point metal that exhibits superconductivity at a temperature equal to or lower than a predetermined temperature. The respective low melting point metals constituting the inner portion 42 of the through electrode 40 and the junction electrode 50 are preferably the same metals as each other.

In the present specification, the high melting point metal is a metal having a melting point of equal to or higher than 800° C., and the low melting point metal is a metal having a melting point of equal to or lower than 300° C. As examples of the high melting point metal that exhibits superconductivity at the temperature equal to or lower than the predetermined temperature, Ta, Nb, V, and Mo, alloys including these as main components, nitrides thereof, or the like are exemplified. As examples of the low melting point metal that exhibits superconductivity at the temperature equal to or lower than the predetermined temperature, Sn, Pb, In, and Ga, alloys including these as main components, or the like are exemplified. Note that the high melting point metal is an example of a first metal in the disclosed technology. The low melting point metal is an example of a low melting point metal in the disclosed technology.

The high melting point metal and the low melting point metal that exhibit superconductivity at the temperature equal to or lower than the predetermined temperature preferably have a small difference from a thermal expansion coefficient of the substrate 20. For example, in a case where the substrate 20 is a Si substrate, Mo or Ta is preferably used as the high melting point metal, and Ga or Sn is preferably used as the low melting point metal.

Furthermore, by using Ga (melting point is 29.8° C.) or In (melting point is 156.6° C.) having a relatively low melting point as the low melting point metal that exhibits superconductivity at the temperature equal to or lower than the predetermined temperature, it is possible to reduce a difference between a temperature at the time of mounting the superconducting device 10 and a temperature at the time of use of the superconducting device 10, and it is possible to suppress volume fluctuation due to temperature fluctuation and stress associated with the volume fluctuation.

Furthermore, metals used as the high melting point metal and the low melting point metal that exhibit superconductivity at the temperature equal to or lower than the predetermined temperature may be selected from a viewpoint of ease of processing. For example, both Ta as the high melting point metal and Sn as the low melting point metal may be patterned by chlorine-based reactive dry etching.

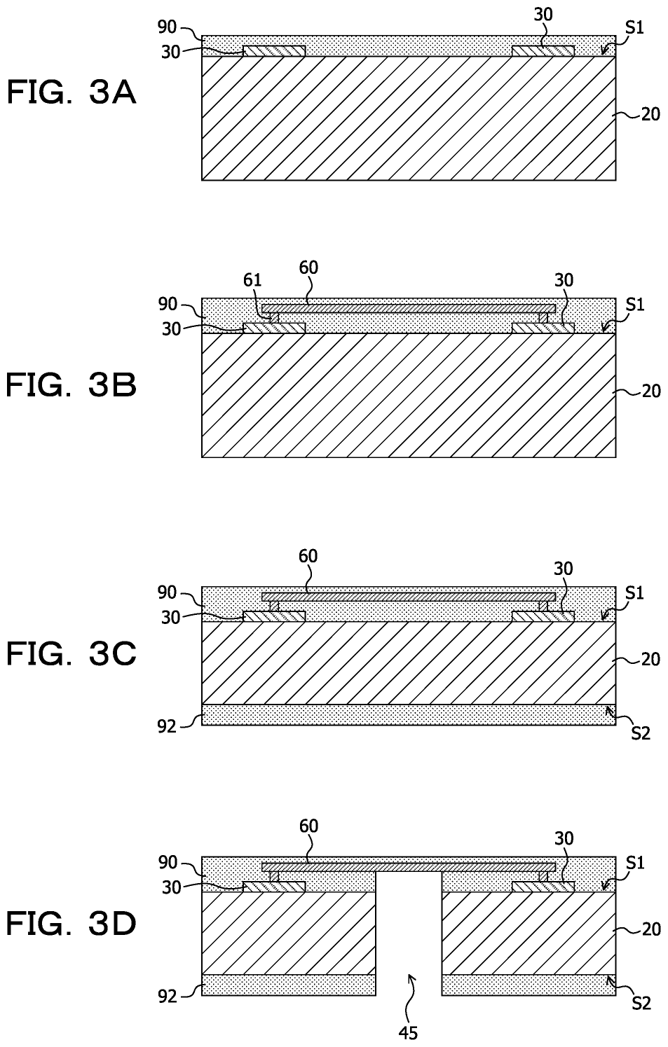

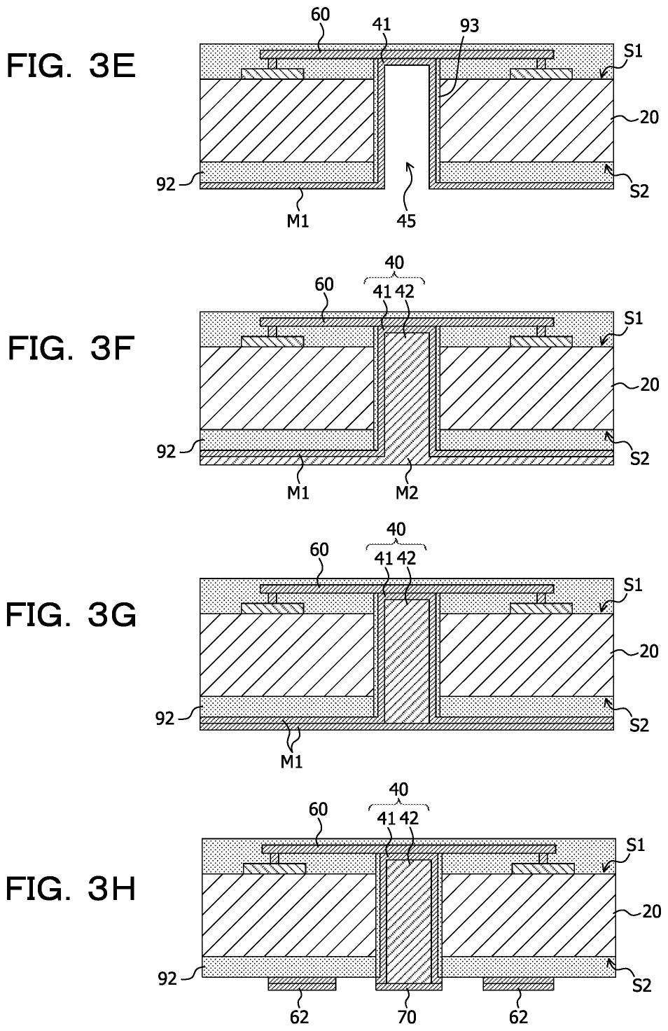

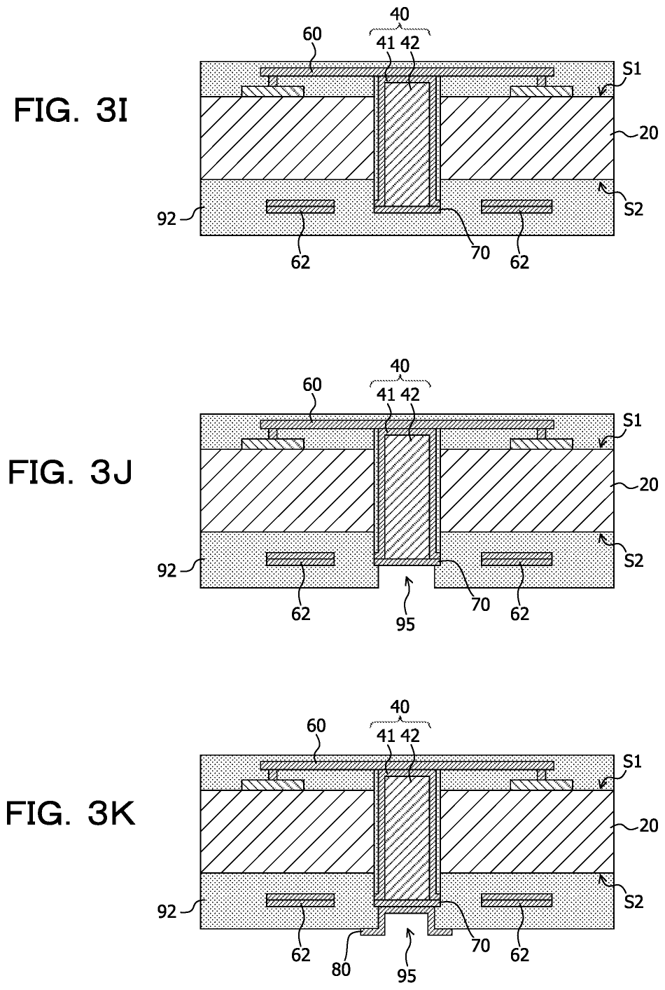

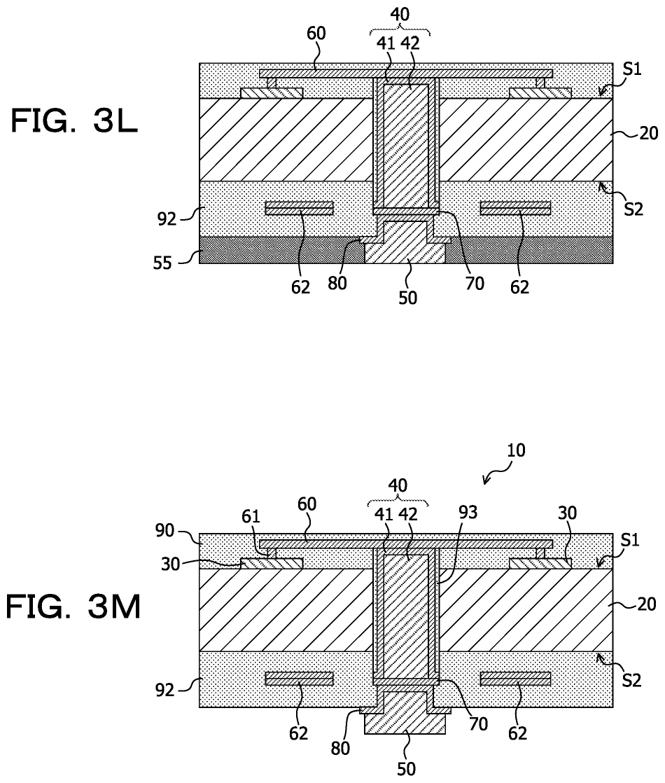

Hereinafter, a method of manufacturing the superconducting device 10 will be described. FIGS. 3A to 3M are cross-sectional views illustrating an example of the method of manufacturing the superconducting device 10.

First, the superconducting qubit elements 30 are formed on the surface S1 of the substrate 20 including a semiconductor such as Si, for example. Next, an insulator film including an insulator such as SiO₂ constituting the insulator layer 90 is formed on the surface S1 of the substrate 20 by, for example, a chemical vapor deposition (CVD) method. The superconducting qubit elements 30 are buried in the insulator layer 90 (FIG. 3A).

Next, after the vias 61 coupled to the superconducting qubit elements 30 are formed, a high melting point metal (for example, Ta) that exhibits superconductivity at a temperature equal to or lower than a predetermined temperature is deposited on a surface of the insulator layer 90 by, for example, a sputtering method. Thereafter, the wiring 60 is formed by patterning the high melting point metal. The wiring 60 is covered with the insulating film including the insulator such as SiO₂ constituting the insulator layer 90 (FIG. 3B). The via 61 includes the same high melting point metal (for example, Ta) as the wiring 60.

Next, the side of the surface S2 of the substrate 20 is ground to thin the substrate 20. Chemical mechanical polishing (CMP) and chemical liquid processing are performed as finishing of the thinning processing of the substrate 20. Next, the insulator layer 92 including an insulator such as SiO₂ is formed on the surface S2 of the substrate 20 by, for example, the CVD method (FIG. 3C).

Next, a through hole 45 penetrating the substrate 20 from the surface of the insulator layer 92 and reaching the wiring 60 is formed by, for example, reactive ion etching using a Bosch process. The Bosch process is a dry etching technology in which three steps of isotropic etching of the substrate 20, deposition of a protective film (not illustrated), and anisotropic etching of the substrate 20 (removal of a protective film on a bottom surface) are repeated to implement vertical deep digging of the substrate 20 at a high speed and a high aspect ratio. When the through hole 45 reaches the wiring 60, etching is stopped (FIG. 3D).

Next, the insulating film 93 including an insulator such as SiO₂ is formed on a side surface of the through hole 45 by, for example, the CVD method. Next, the same high melting point metal M1 (for example, Ta) as that of the wiring 60 is deposited on the side of the surface S2 of the substrate 20 by, for example, the sputtering method. The surface of the insulator layer 92, and the side surface and a bottom surface of the through hole 45 are covered with the high melting point metal M1. A portion covering the side surface and the bottom surface of the through hole 45 of the high melting point metal M1 becomes the outer portion 41 of the through electrode 40, and a portion covering the surface of the insulator layer 92 of the high melting point metal M1 becomes a part of the dummy wiring 62. The outer portion 41 of the through electrode 40 is coupled to the wiring 60 on the bottom surface of the through hole 45 (FIG. 3E).

Next, a seed layer (not illustrated) is formed on a surface of the high melting point metal M1 by, for example, the sputtering method, and then a low melting point metal M2 (for example, Sn) that exhibits superconductivity at a temperature equal to or lower than a predetermined temperature is deposited on the high melting point metal M1 by a plating method. The through hole 45 is filled with the low melting point metal M2, thereby forming the inner portion 42 of the through electrode 40 (FIG. 3F).

Next, the excessive low melting point metal M2 deposited on the insulator layer 92 is removed by, for example, the CMP. Thereafter, the same high melting point metal M1 (for example, Ta) as those of the wiring 60 and the outer portion 41 of the through electrode 40 is further deposited on the side of the surface S2 of the substrate 20 by, for example, the sputtering method (FIG. 3G).

Next, the high melting point metal M1 is patterned. With this configuration, the dummy wirings 62 are formed on the side of the surface S2 of the substrate 20, and the cap film 70 that closes the end portion of the through electrode 40 on the side of the surface S2 of the substrate 20 is formed (FIG. 3H).

The dummy wirings 62 are covered with an insulating film including the insulator such as SiO₂ constituting the insulator layer 92 (FIG. 3I). Next, a contact hole 95 reaching the cap film 70 from the surface of the insulator layer 92 is formed by, for example, the reactive ion etching (FIG. 3J).

Next, the same high melting point metal (for example, Ta) as those of the wiring 60, the outer portion 41 of the through electrode 40, the cap film 70, and the dummy wirings 62 is deposited on the side of the surface S2 of the substrate 20 by, for example, the sputtering method, and the high melting point metal is patterned to form the base film 80. The base film 80 is coupled to the cap film 70 on a bottom surface of the contact hole 95 (FIG. 3K).

Next, a solder resist 55 is formed on the surface of the insulator layer 92. The solder resist 55 is provided with an opening through which the base film 80 is exposed. Next, the same low melting point metal (for example, Sn) as that of the inner portion 42 of the through electrode 40 is deposited on the base film 80 by the plating method. With this configuration, the junction electrode 50 is formed (FIG. 3L). Finally, the solder resist 55 is removed (FIG. 3M).

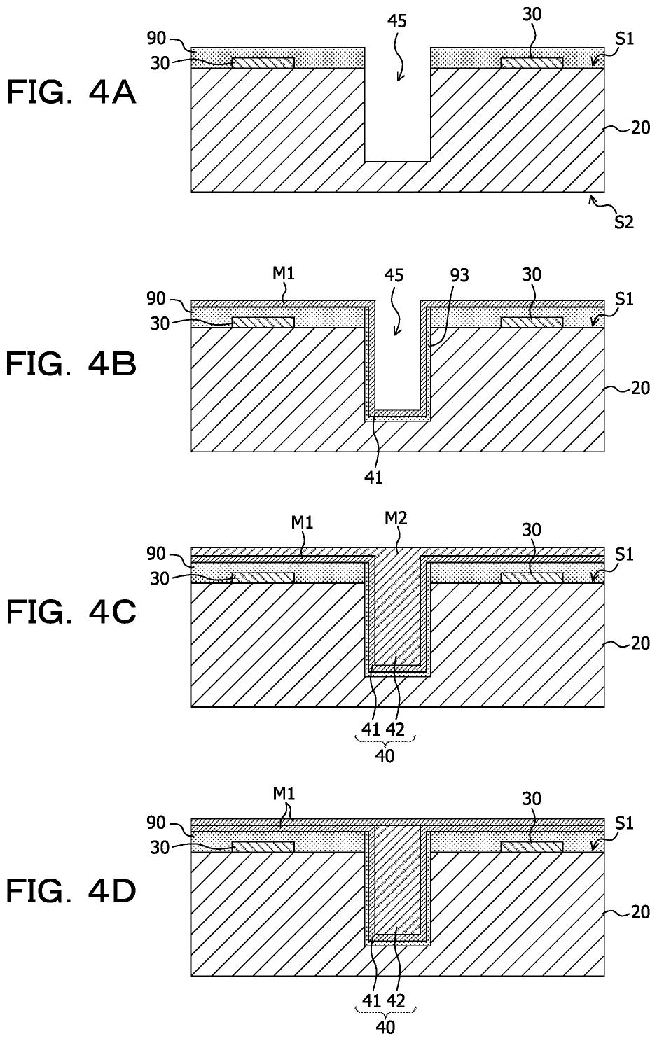

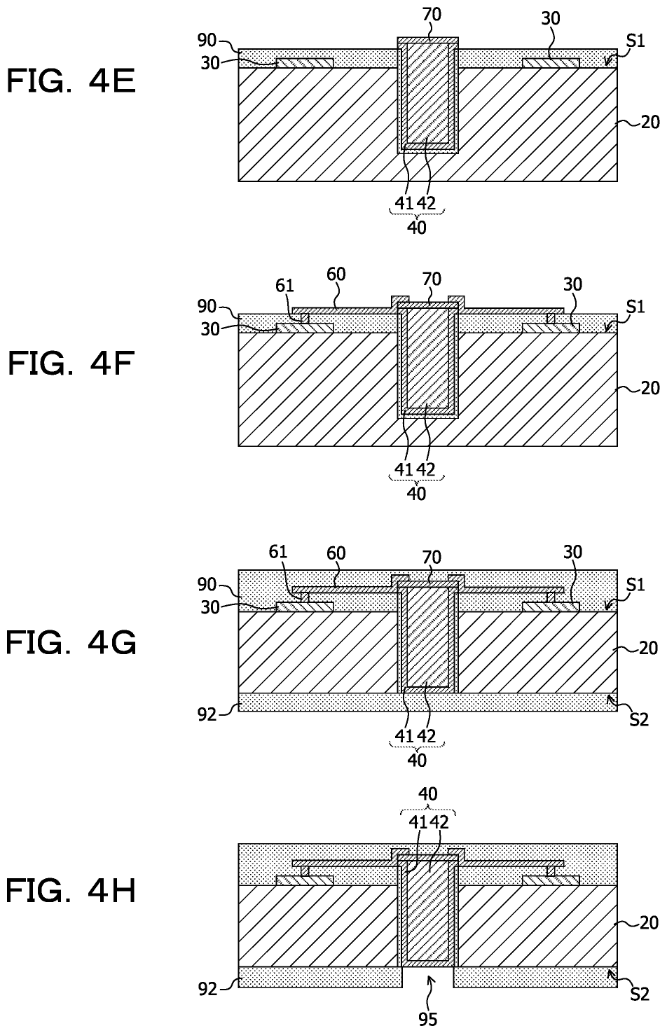

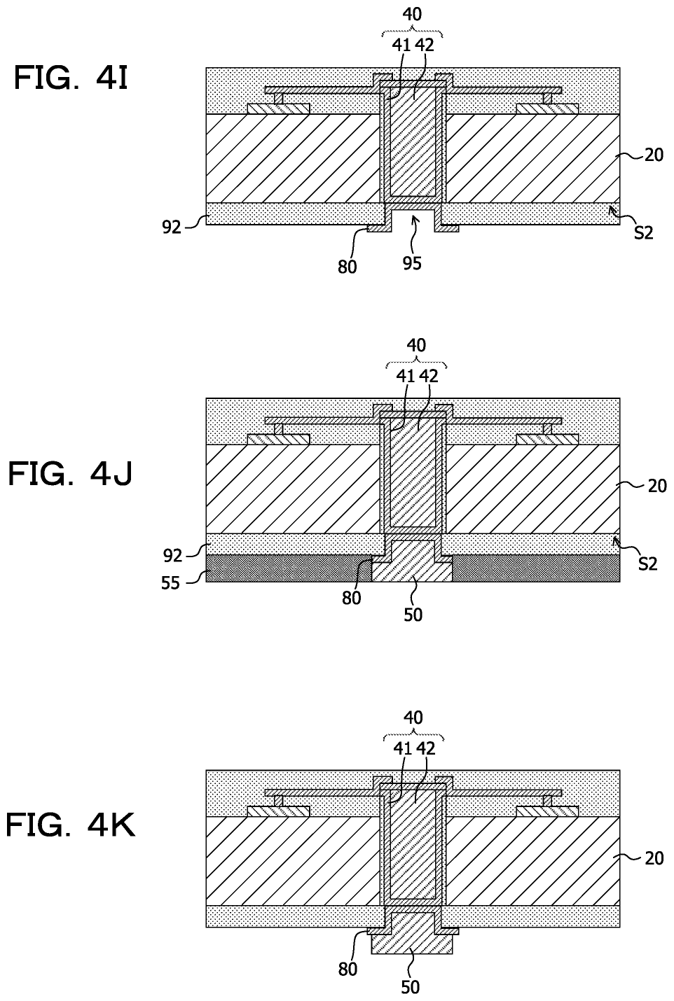

In the description above, the method of manufacturing in a case where the through hole 45 for forming the through electrode 40 is formed from the side of the surface S2 of the substrate 20 has been exemplified, but the through hole 45 may also be formed from the side of the surface S1 of the substrate 20. Hereinafter, a method of manufacturing in a case where the through hole 45 is formed from the side of the surface S1 of the substrate 20 will be described with reference to FIGS. 4A to 4K.

The through hole 45 is formed from the side of the surface S1 of the substrate 20 on which the superconducting qubit element 30 and the insulator layer 90 are formed by, for example, the reactive ion etching using the Bosch process. The etching is stopped before the through hole 45 reaches the surface S2 (FIG. 4A).

Next, the insulating film 93 including an insulator such as SiO₂ is formed on the side surface and the bottom surface of the through hole 45 by, for example, the CVD method. Next, the high melting point metal M1 (for example, Ta) that exhibits superconductivity at the temperature equal to or lower than the predetermined temperature is deposited on the side of the surface S1 of the substrate 20 by, for example, the sputtering method. The surface of the insulator layer 90, and the side surface and the bottom surface of the through hole 45 are covered with the high melting point metal M1. A portion covering the side surface and the bottom surface of the through hole 45 of the high melting point metal M1 becomes the outer portion 41 of the through electrode 40 (FIG. 4B).

Next, a seed layer (not illustrated) is formed on the surface of the high melting point metal M1 by, for example, the sputtering method, and then the low melting point metal M2 (for example, Sn) that exhibits superconductivity at the temperature equal to or lower than the predetermined temperature is deposited on the high melting point metal M1 by the plating method. The through hole 45 is filled with the low melting point metal M2, thereby forming the inner portion 42 of the through electrode 40 (FIG. 4C).

Next, the excessive low melting point metal M2 deposited on the insulator layer 90 is removed by, for example, the CMP. Thereafter, the same high melting point metal M1 (for example, Ta) as that of the outer portion 41 of the through electrode 40 is further deposited on the side of the surface S1 of the substrate 20 by, for example, the sputtering method (FIG. 4D).

Next, the high melting point metal M1 is patterned. With this configuration, the cap film 70 that closes an end portion of the through electrode 40 on the side of the surface S1 of the substrate 20 is formed (FIG. 4E).

Next, after the vias 61 coupled to the superconducting qubit elements 30 are formed, the same high melting point metal (for example, Ta) as those of the outer portion 41 of the through electrode 40 and the cap film 70 is deposited on the side of the surface S1 of the substrate 20 by, for example, the sputtering method, and the high melting point metal is patterned. With this configuration, the wiring 60 electrically coupled to the superconducting qubit elements 30 and the through electrode 40 is formed (FIG. 4F).

The wiring 60 is covered with the insulating film including the insulator such as SiO₂ constituting the insulator layer 90. Next, the side of the surface S2 of the substrate 20 is ground to thin the substrate 20 until the through electrode 40 is exposed. The CMP and the chemical liquid processing are performed as finishing of the thinning processing of the substrate 20. Next, the insulator layer 92 including an insulator such as SiO₂ is formed on the surface S2 of the substrate 20 by, for example, the CVD method (FIG. 4G).

Next, the contact hole 95 reaching the through electrode 40 from the surface of the insulator layer 92 is formed by, for example, the reactive ion etching (FIG. 4H). Next, the same high melting point metal (for example, Ta) as those of the wiring 60, the outer portion 41 of the through electrode 40, and the cap film 70 is deposited on the side of the surface S2 of the substrate 20 by, for example, the sputtering method, and the high melting point metal is patterned to form the base film 80. The base film 80 is coupled to the through electrode 40 on the bottom surface of the contact hole 95 (FIG. 4I).

Next, the solder resist 55 is formed on the surface of the insulator layer 92. The solder resist 55 is provided with the opening through which the base film 80 is exposed. Next, the same low melting point metal (for example, Sn) as that of the inner portion 42 of the through electrode 40 is deposited on the base film 80 by the plating method. With this configuration, the junction electrode 50 is formed (FIG. 4J). Finally, the solder resist 55 is removed (FIG. 4K).

As described above, according to the superconducting device 10 according to the present embodiment, since the through electrode 40 penetrating the substrate 20 is included, it is possible to perform three-dimensional mounting in which the superconducting device 10 and another device are laminated. The superconducting device 10 is joined to another device via the junction electrode 50. In the joining between the superconducting device 10 and another device, the reflow processing for melting the junction electrode 50 is performed. Volumes of the junction electrode 50 and the through electrode 40 may fluctuate due to heating in the reflow processing. In the superconducting device 10 according to the present embodiment, the junction electrode 50 is disposed immediately below the through electrode 40, a volume of the structure in which the junction electrode 50 and the through electrode 40 are integrated tends to increase, and stress due to volume fluctuation becomes a problem. However, in the superconducting device 10 according to the present embodiment, the cap film 70 and the base film 80 including the high melting point metals function as the partition walls separating the through electrode 40 and the junction electrode 50. In general, the high melting point metal has a smaller thermal expansion coefficient than that of the low melting point metal, and thus the volume fluctuation in the through electrode 40 and the volume fluctuation in the junction electrode 50 may be divided by separating the through electrode 40 and the junction electrode 50 from each other by the partition walls formed of the high melting point metals. With this configuration, it is possible to suppress the stress associated with the volume fluctuation in the through electrode 40 and the junction electrode 50.

Furthermore, the low melting point metal constituting the inner portion 42 of the through electrode 40 is completely surrounded (sealed) by the high melting point metal constituting the outer portion of the through electrode 40 and the high melting point metal constituting the cap film 70. Since the volume fluctuation associated with temperature change of the inner portion 42 of the through electrode 40 is limited by the high melting point metals surrounding the inner portion 42 of the through electrode 40, the volume fluctuation associated with the temperature change of the through electrode 40 may be suppressed. Furthermore, although the low melting point metal constituting the inner portion 42 of the through electrode 40 may be melted in the reflow processing, the high melting point metal constituting the outer portion 41 of the through electrode 40 is not melted, so that diffusion of the melted low melting point metal constituting the inner portion 42 into the substrate 20 may be suppressed.

Furthermore, in the superconducting device 10 according to the present embodiment, all of the wiring 60, the outer portion 41 of the through electrode 40, the cap film 70, and the base film 80 include the same high melting point metal. With this configuration, alloy formation in a case where dissimilar metals are used is avoided. When an alloy is formed, a decoherence effect increases, and it may be difficult to maintain a quantum mechanical superposition state.

Note that, in the description above, a mode in which the inner portion 42 of the through electrode 40 includes the low melting point metal that exhibits superconductivity at the temperature equal to or lower than the predetermined temperature has been exemplified, but the present disclosure is not limited to this. For example, the inner portion 42 of the through electrode 40 may include the same kind of material as that of the substrate 20 or an oxide of the material constituting the substrate 20. In other words, the inside of the through electrode 40 may be filled with the same kind of material as that of the substrate 20 or the oxide of the material constituting the substrate 20. For example, in a case where the substrate 20 is a Si substrate, the inner portion 42 of the through electrode 40 may include polysilicon or SiO₂. The same kind of material as that of the substrate 20 or the oxide of the material constituting the substrate 20, which constitutes the inner portion 42 of the through electrode 40, is surrounded by the high melting point metal that exhibits superconductivity at the temperature equal to or lower than the predetermined temperature. Since the inner portion 42 of the through electrode 40 includes the same kind of material as that of the substrate 20 or the oxide of the material constituting the substrate 20, the volume fluctuation associated with the temperature change of the through electrode 40 and the substrate 20 occurs at substantially the same ratio (in other words, thermal expansion coefficients of the through electrode 40 and the substrate 20 are substantially the same), the stress associated with the temperature change may be suppressed.

Furthermore, the inner portion 42 of the through electrode 40 may include an insulator. Furthermore, the inner portion 42 of the through electrode 40 may include the same high melting point metal as that of the outer portion 41 of the through electrode 40. With this configuration, as compared with a case where the inner portion 42 of the through electrode 40 includes the low melting point metal, it is possible to suppress the volume fluctuation associated with the temperature change of the through electrode 40. Note that, since it is generally difficult to form a film of the high melting point metal by the plating method, the sputtering method or the CVD method is applied as a film formation method for charging the inside of the through electrode 40.

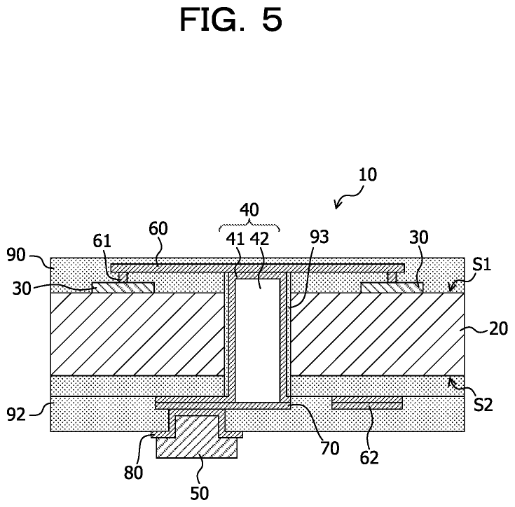

Furthermore, as illustrated in FIG. 5, the inner portion 42 of the through electrode 40 may be a cavity. With this configuration, as compared with a case where the inner portion 42 of the through electrode 40 includes the low melting point metal, it is possible to suppress the volume fluctuation associated with the temperature change of the through electrode 40. In the case where the inner portion 42 of the through electrode 40 is assumed to be the cavity, the junction electrode 50 is preferably provided at a position shifted from that of the through electrode 40 in a main surface direction of the substrate 20 from a viewpoint of securing mechanical strength. Note that, since the through electrode 40 exhibits superconductivity, electric resistance does not become a problem. Therefore, the through electrode 40 may include only a thin high melting point metal constituting the outer portion 41.

### Second Embodiment

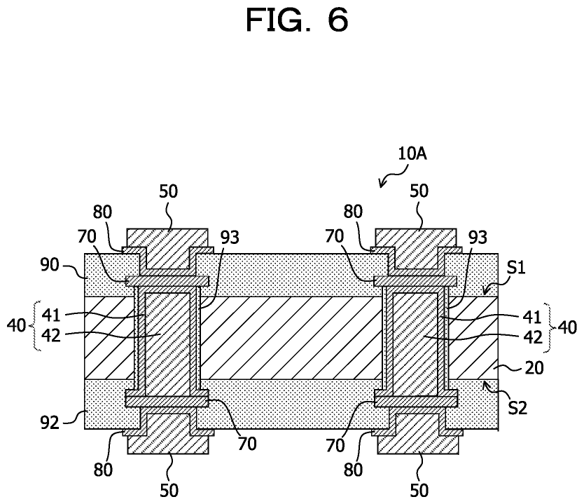

FIG. 6 is a cross-sectional view illustrating an example of a configuration of a superconducting device 10A according to a second embodiment of the disclosed technology. The superconducting device 10A according to the present embodiment has a form of an interposer that mediates signal transmission between devices, and is different from the superconducting device 10 according to the first embodiment in that a superconducting qubit element is not included. The superconducting device 10A includes a substrate 20, through electrodes 40, and junction electrodes 50.

The substrate 20 includes an insulator or a semiconductor. Use of a semiconductor such as silicon as the substrate 20 facilitates application of an existing semiconductor processing technology.

One end of the through electrode 40 is coupled to the junction electrode 50 via a cap film 70 provided on a side of a surface S1 of the substrate 20, and the other end is coupled to the junction electrode 50 via a cap film 70 provided on a side of a surface S2 of the substrate 20.

An outer portion 41 of the through electrode 40 includes a high melting point metal that exhibits superconductivity at a temperature equal to or lower than a predetermined temperature, and surrounds an inner portion 42. The inner portion 42 of the through electrode 40 includes a low melting point metal that exhibits superconductivity at a temperature equal to or lower than a predetermined temperature. Both ends of the through electrode 40 are closed by the cap films 70. The cap film 70 includes the same high melting point metal as that of the outer portion 41 of the through electrode 40. The cap film 70 functions as a partition wall separating the through electrode 40 and the junction electrode 50. The low melting point metal constituting the inner portion 42 of the through electrode 40 is completely surrounded (sealed) by the high melting point metal constituting the outer portion 41 of the through electrode 40 and the high melting point metal constituting the cap film 70.

The junction electrodes 50 are provided on both the side of the surface S1 and the side of the surface S2 of the substrate 20. The junction electrode 50 includes the same low melting point metal as that of the inner portion 42 of the through electrode 40. Base films 80 are interposed between the junction electrodes 50 and insulator layers 90 and 92. The base films 80 function as so-called under bump metals, and have a function of suppressing diffusion of the low melting point metals constituting the junction electrodes 50 into the insulator layers 90 and 92 and a function of enhancing adhesion between the junction electrodes 50 and the insulator layers 90 and 92. Furthermore, the base films 80 function as partition walls separating the through electrode 40 and the junction electrode 50. The base film 80 includes the same high melting point metal as those of the outer portions 41 of the through electrodes 40 and the cap films 70.

The junction electrodes 50 on the side of the surface S1 of the substrate 20 are joined to a first device (not illustrated), and the junction electrodes 50 on the side of the surface S2 of the substrate 20 are joined to a second device (not illustrated). The first device and the second device may perform signal transmission via the through electrodes 40. Note that, since various processes for manufacturing the superconducting device 10 according to the first embodiment may be applied to a method of manufacturing the superconducting device 10A according to the present embodiment, description thereof will be omitted.

According to the superconducting device 10A according to the present embodiment, similarly to the superconducting device 10 according to the first embodiment, since the through electrodes 40 and the junction electrodes 50 are divided by the partition walls, it is possible to suppress stress associated with temperature change.

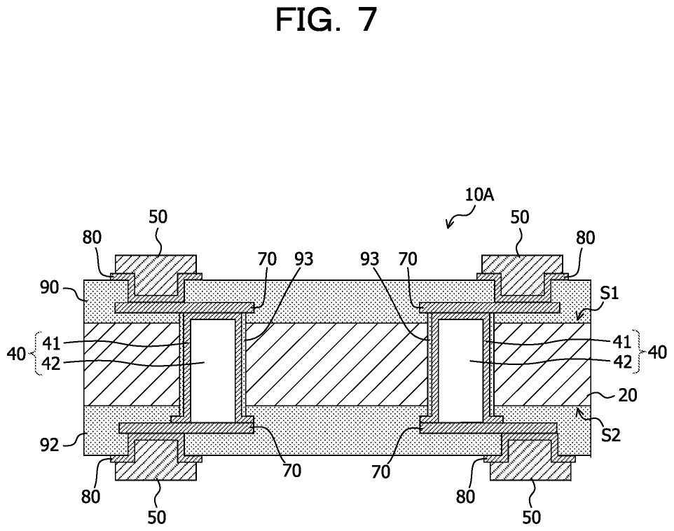

Note that the inner portion 42 of the through electrode 40 may include the same kind of material as that of the substrate 20 or an oxide of the material constituting the substrate 20. Furthermore, the inner portion 42 of the through electrode 40 may include an insulator. Furthermore, the inner portion 42 of the through electrode 40 may include the same high melting point metal as that of the outer portion 41 of the through electrode 40. Furthermore, as illustrated in FIG. 7, the inner portion 42 of the through electrode 40 may be a cavity. In the case where the inner portion 42 of the through electrode 40 is assumed to be the cavity, the junction electrode 50 is preferably provided at a position shifted from that of the through electrode 40 in a main surface direction of the substrate 20 from a viewpoint of securing mechanical strength.

### Third Embodiment

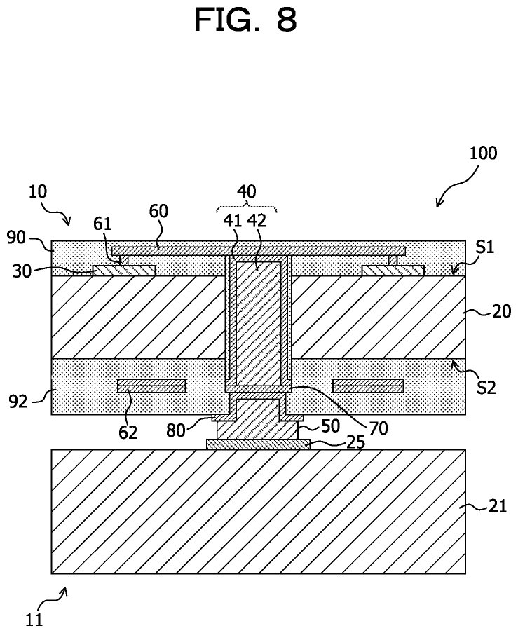

FIG. 8 is a cross-sectional view illustrating an example of a configuration of a laminated body 100 according to a third embodiment of the disclosed technology. The laminated body 100 is formed by laminating the superconducting device 10 according to the first embodiment described above and another device 11. The another device 11 may be, for example, a reading device having a function of reading a qubit output from the superconducting device 10. The junction electrode 50 of the superconducting device 10 is joined to a pad 25 provided on a surface of a substrate 21 of the another device 11.

In the joining between the superconducting device 10 and the another device 11, reflow processing for melting the junction electrode 50 is performed. In the superconducting device 10, the cap film 70 and the base film 80 including the high melting point metal function as the partition walls separating the through electrode 40 and the junction electrode 50, so that the volume fluctuation in the through electrode 40 and the volume fluctuation in the junction electrode 50 may be divided. With this configuration, it is possible to suppress the stress associated with the volume fluctuation in the through electrode 40 and the junction electrode 50.

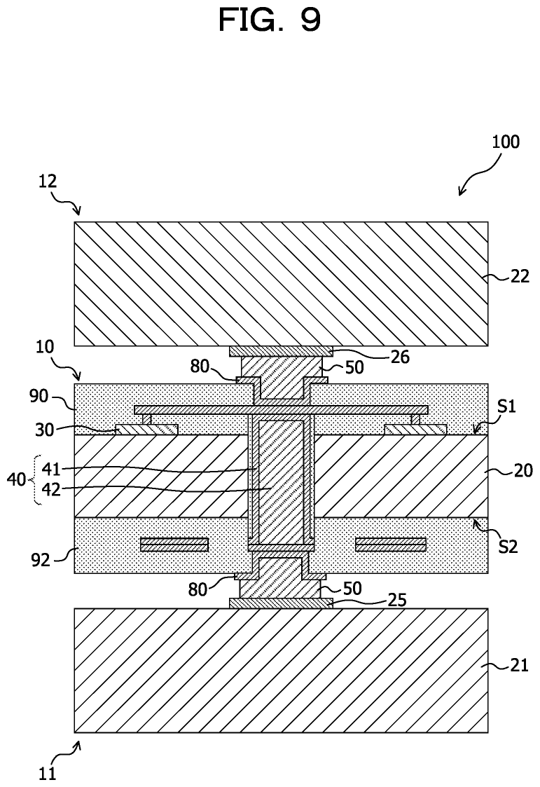

Note that, as illustrated in FIG. 9, in the superconducting device 10, the junction electrodes 50 may be provided on both the side of the surface S1 and the side of the surface S2 of the substrate 20, and another devices 11 and 12 may be laminated on both the side of the surface S1 and the side of the surface S2 of the substrate 20. The junction electrode 50 on the side of the surface S2 of the superconducting device 10 is joined to the pad 25 provided on the surface of the substrate 21 of the another device 11, and the junction electrode 50 on the side of the surface S1 of the superconducting device 10 is joined to a pad 26 provided on a surface of a substrate 22 of the another device 12.

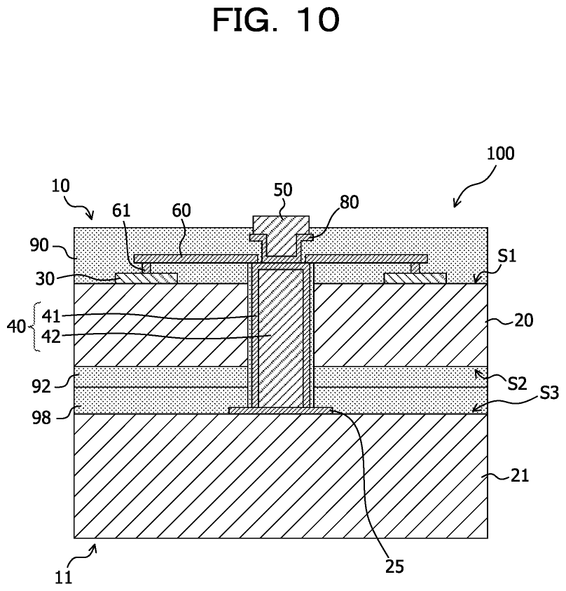

Furthermore, as illustrated in FIG. 10, the joining between the superconducting device 10 and the another device 11 may be normal temperature joining or joining with an adhesive instead of joining via the junction electrode 50. In the laminated body 100 illustrated in FIG. 10, the through electrode 40 is formed after the insulator layer 92 provided on the side of the surface S2 of the substrate 20 of the superconducting device 10 and an insulator layer 98 provided on a side of a surface S3 of the substrate 21 of the another device 11 are joined to each other by normal temperature joining or joined with an adhesive. The through electrode 40 is coupled to the pad 25 provided on the surface of the substrate 21 of the another device 11. The superconducting device 10 includes the junction electrode 50 provided on the side of the surface S1 of the substrate 20. Still another device (not illustrated) may be joined onto the superconducting device 10 via the junction electrode 50.

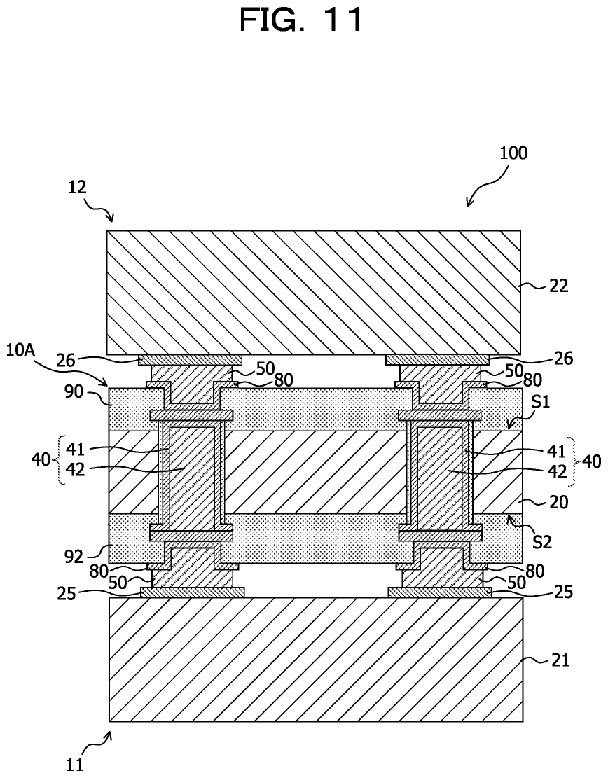

FIG. 11 is a cross-sectional view illustrating an example of a configuration of the laminated body including the superconducting device 10A according to the second embodiment described above and the another devices 11 and 12. The superconducting device 10A is an interposer that mediates signal transmission in the another devices 11 and 12. For example, the another device 12 may have a function of outputting a qubit, and the another device 11 may have a function of reading a qubit. The junction electrodes 50 on the side of the surface S2 of the superconducting device 10A are joined to the pads 25 provided on the surface of the substrate 21 of the another device 11, and the junction electrodes 50 on the side of the surface S1 of the superconducting device 10A are joined to the pads 26 provided on the surface of the substrate 22 of the another device 12.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A superconducting device comprising:
a substrate;
a through hole provided in the substrate;
a through electrode that is an electrode provided in the through hole and that includes a first portion and a second portion provided between the first portion and an inner wall surface of the through hole, in which the second portion is formed of a material that includes a first metal that exhibits superconductivity at a temperature equal to or lower than a predetermined temperature;
a junction electrode that is an electrode electrically coupled to the through electrode, that has at least a part provided outside the through hole, and that is formed of a material that includes a second metal that exhibits superconductivity at a temperature equal to or lower than a predetermined temperature; and
a partition wall that is provided between the through electrode and the junction electrode and that is formed of a material that includes the first metal,
wherein a melting point of the first metal is higher than a melting point of the second metal.

2. The superconducting device according to claim 1, further comprising:
a superconducting qubit element provided on the substrate; and
a wiring that is electrically coupled to the superconducting qubit element and the through electrode and that is formed of a material that includes the first metal.

3. The superconducting device according to claim 2, further comprising
a dummy wiring that is provided on a side of a surface of the substrate opposite to a surface of a side on which the wiring is provided and that is not coupled to the superconducting qubit element.

4. The superconducting device according to claim 1, wherein
the junction electrode has a portion provided in an insulator layer, and
a base film formed of a material that includes the first metal is further included between the junction electrode and the insulator layer.

5. The superconducting device according to claim 1, wherein
the second portion and the partition wall surround the first portion.

6. The superconducting device according to claim 5, wherein
the first portion is formed of a material that includes the second metal.

7. The superconducting device according to claim 5, wherein
the first portion is formed of a material that includes the first metal.

8. The superconducting device according to claim 5, wherein
the first portion is formed of the same kind of material as a material of the substrate or a material that includes an oxide of the material that constitutes the substrate.

9. The superconducting device according to claim 5, wherein
the first portion is a cavity.

10. The superconducting device according to claim 9, wherein
the junction electrode is provided at a position shifted from a position of the through electrode in a main surface direction of the substrate.

11. A method of manufacturing a superconducting device, comprising processing of:
forming, in a substrate, a through hole that penetrates the substrate;
forming, in the through hole, a through electrode that includes a first portion disposed in the through hole and a second portion provided between the first portion and an inner wall surface of the through hole, in which the second portion is formed of a material that includes a first metal that exhibits superconductivity at a temperature equal to or lower than a predetermined temperature;
forming a partition wall that includes the first metal on a bottom surface of the through electrode; and
forming a junction electrode that is in contact with the partition wall, that is electrically coupled to the through electrode, and that is formed of a material that includes a second metal that exhibits superconductivity at a temperature equal to or lower than a predetermined temperature,
wherein a melting point of the first metal is higher than a melting point of the second metal.

12. The method of manufacturing according to claim 11, further comprising:
forming a wiring that electrically couples a superconducting qubit element provided on the substrate and the through electrode and that is formed of a material that includes the first metal.

13. The method of manufacturing according to claim 11, wherein
the forming of the through electrode includes
covering an inner wall surface and a bottom surface of the through hole with a material that includes the first metal via an insulating film.

14. The method of manufacturing according to claim 13, wherein
the forming of the through electrode includes
filling a material that includes the second metal inside the through hole in which the second portion is formed and forming the first portion.

15. The method of manufacturing according to claim 13, wherein
the forming of the through electrode includes
filling a material that includes the first metal inside the through hole in which the second portion is formed and forming the first portion.

16. The method of manufacturing according to claim 13, wherein
the forming of the through electrode includes
filling the same material as a material of the substrate or a material that includes an oxide of the material inside the through hole in which the second portion is formed, and forming the first portion.

17. The method of manufacturing according to claim 13, wherein
the forming of the partition wall includes
covering an end portion of the through hole with a material that includes the first metal so as to close inside of the through hole before the junction electrode is formed.

18. The method of manufacturing according to claim 11, wherein
the forming of the junction electrode includes:
forming an opening that reaches the partition wall in an insulator layer provided on a surface of the substrate;
forming a base film that includes the first metal on a surface of the opening of the insulator layer; and
depositing a material that includes the second metal on the base film.

19. A laminated body in which a superconducting device and another device are laminated,
the superconducting device including:
a substrate;
a through hole provided in the substrate;
a through electrode that is an electrode provided in the through hole, that includes a first portion and a second portion provided between the first portion and an inner wall surface of the through hole, and that is formed of a material that includes a first metal that exhibits superconductivity at a temperature equal to or lower than a predetermined temperature;
a junction electrode that is an electrode electrically coupled to the through electrode, that has at least a part provided outside the through hole, and that is formed of a material that includes a second metal that exhibits superconductivity at a temperature equal to or lower than a predetermined temperature; and
a partition wall that is provided between the through electrode and the junction electrode and that is formed of a material that includes the first metal,
wherein a melting point of the first metal is higher than a melting point of the second metal.

20. The laminated body according to claim 19, wherein
the junction electrode is coupled to the another device.
